(19) United States
(12) Patent Application Publication
(10) Pub. No.: US 2014/0070805 A1
(43) Pub. Date: Mar. 13, 2014

(54) MR IMAGING WITH B1 MAPPING

(71) Applicants: Peter Van Der Meulen, Best (NL); Peter Boernert, Hamburg (DE); Kay Nehrke, Ammersbek (DE)

(72) Inventors: Peter Van Der Meulen, Best (NL); Peter Boernert, Hamburg (DE); Kay Nehrke, Ammersbek (DE)

(73) Assignee: KONINKLIJKE PHILIPS N.V., EINDHOVEN (NL)

(21) Appl. No.: 14/008,126

(22) PCT Filed: Apr. 2, 2012
(86) PCT No.: PCT/IB12/51590

§ 371 Date: Sep. 27, 2013

(30) Foreign Application Priority Data
Apr. 11, 2011 (EP) 11161806.2

(51) Int. Cl. G01R 33/28

(52) U.S. Cl. CPC G01R 33/288
USPC 324/309; 324/322

(57) ABSTRACT

The invention relates to a method of MR imaging, wherein a portion of a body is subjected to an imaging sequence of RF pulses and switched magnetic field gradients, which imaging sequence is a stimulated echo sequence including an off-resonant Bloch-Siegert RF pulse (BS) radiated during a preparation period (21) of the stimulated echo sequence. A B₁ map is derived from the acquired stimulated echo MR signals. Moreover, the invention relates to a method of MR imaging, wherein a portion of a body is subjected to a first imaging sequence, which comprises a first composite excitation RF pulse consisting of two RF pulse components having essentially equal flip angles and being out of phase by essentially 90°. Further, the portion of the body is subjected to a second imaging sequence, wherein a B₁ map is derived from signal data acquired by means of the first and second imaging sequences.

### TECHNICAL FIELD

The invention relates to the field of magnetic resonance (MR) imaging. It concerns methods of MR imaging of at least a portion of a body. The invention also relates to a MR device and to a computer program to be run on a MR device.

Image-forming MR methods which utilize the interaction between magnetic fields and nuclear spins in order to form two-dimensional or three-dimensional images are widely used nowadays, notably in the field of medical diagnostics, because for the imaging of soft tissue they are superior to other imaging methods in many respects, do not require ionizing radiation and are usually not invasive.

### BACKGROUND OF THE INVENTION

According to the MR method in general, the body of the patient to be examined is arranged in a strong, uniform magnetic field (B₀ field) whose direction at the same time defines an axis (normally the z-axis) of the co-ordinate system on which the measurement is based. The magnetic field produces different energy levels for the individual nuclear spins in dependence on the magnetic field strength which can be excited (spin resonance) by application of an electromagnetic alternating field (RF field, also referred to as B₁ field) of defined frequency (so-called Larmor frequency, or MR frequency). From a macroscopic point of view the distribution of the individual nuclear spins produces an overall magnetization which can be deflected out of the state of equilibrium by application of an electromagnetic pulse of appropriate frequency (RF pulse) while the magnetic field extends perpendicular to the z-axis, so that the magnetization performs a precessional motion about the z-axis. The precessional motion describes a surface of a cone whose angle of aperture is referred to as flip angle. The magnitude of the flip angle is dependent on the strength and the duration of the applied electromagnetic pulse. In the case of a so-called 90° pulse, the spins are deflected from the z axis to the transverse plane (flip angle 90°).

After termination of the RF pulse, the magnetization relaxes back to the original state of equilibrium, in which the magnetization in the z direction is built up again with a first time constant T₁ (spin lattice or longitudinal relaxation time), and the magnetization in the direction perpendicular to the z direction relaxes with a second time constant T₂ (spin-spin or transverse relaxation time). The variation of the magnetization can be detected by means of one or more receiving RF coils which are arranged and oriented within an examination volume of the MR device in such a manner that the variation of the magnetization is measured in the direction perpendicular to the z-axis. The decay of the transverse magnetization is accompanied, after application of, for example, a 90° pulse, by a transition of the nuclear spins (induced by local magnetic field inhomogeneities) from an ordered state with the same phase to a state in which all phase angles are uniformly distributed (dephasing). The dephasing can be compensated by means of a refocusing pulse (for example a 180° pulse). This produces an echo signal (spin echo) in the receiving coils.

In order to realize spatial resolution in the body, linear magnetic field gradients extending along the three main axes are superposed on the uniform magnetic field, leading to a linear spatial dependency of the spin resonance frequency. The signal picked up in the receiving coils then contains components of different frequencies which can be associated with different locations in the body. The MR signal data obtained via the RF coils corresponds to the spatial frequency domain and is called k-space data. The k-space data usually includes multiple lines acquired with different phase encoding. Each line is digitized by collecting a number of samples. A set of k-space data is converted to a MR image by means of Fourier transformation.

It is generally desirable to have a relatively uniform homogeneity of the generated RF field (B₁ field) for excitation of magnetic resonance throughout a cross section of the imaged portion of the patient's body. However, as the MR frequency increases with increasing main magnetic field strength, this becomes more difficult due to conductive losses and wavelength effects within the body of the patient. Against this background, an accurate measurement of the spatial distribution of the transmitted RF field is important for many MR imaging applications. This requires a robust and fast B₁ mapping technique.

Recently, a B₁ mapping technique based on the so-called Bloch-Siegert shift has been proposed (Sacolick et al.: “B₁ mapping by Bloch-Siegert shift”, Magnetic Resonance in Medicine, 2010, Vol. 63, p. 1315-1322). Unlike conventionally applied double-angle or other signal magnitude-based methods, it encodes the B₁ information into MR signal phase, which results in important advantages in terms of acquisition speed, accuracy, and robustness. The Bloch-Siegert frequency shift is caused by irradiating an off-resonant RF pulse following conventional (on-resonant) RF pulses used for spin excitation. When applying the off-resonant Bloch-Siegert RF pulse, a spin precession frequency shift is observed. This shift is proportional to the square of the magnitude of B₁. By means of appropriate gradient-encoding the off-resonant Bloch-Siegert pulse allows to acquire spatially resolved B₁ maps. Voxel-wise phase differences of two MR image acquisitions, with the off-resonant Bloch-Siegert RF pulse applied at two frequencies symmetrically around the MR resonance frequency, are used to eliminate undesired off-resonance effects due to main magnetic field inhomogeneities and chemical shift.

A drawback of the above described B₁ mapping technique by Bloch-Siegert shifts results from the fact that relatively long and strong off-resonant Bloch-Siegert RF pulses are required in order to induce a significant phase difference for accurate B₁ mapping. This results in a high SAR (specific absorption rate) which can easily exceed the physiologically tolerable limits. Consequently, the allowed repetition time and, hence, scan time is increased, and the method becomes prone to motion-induced artifacts.

From the foregoing it is readily appreciated that there is a need for an improved B₁ mapping method.

### SUMMARY OF THE INVENTION

In accordance with the invention, a method of MR imaging of at least a portion of a body of a patient is disclosed. The method comprises the steps of:

subjecting the portion of the body to an imaging sequence of RF pulses and switched magnetic field gradients, which imaging sequence is a stimulated echo sequence including:
i) at least two preparation RF pulses radiated toward the portion of the body during a preparation period,
ii) an off-resonant Bloch-Siegert RF pulse radiated toward the portion of the body during the preparation period within a time interval between the at least two preparation RF pulses, and
iii) one or more refocusing RF pulses radiated toward the portion of the body during an acquisition period temporally subsequent to the preparation period;

acquiring one or more stimulated echo MR signals during the acquisition period;

deriving a B₁ map indicating the spatial distribution of the RF field of the RF pulses within the portion of the body from the acquired stimulated echo MR signals.

According to the invention, the known Bloch-Siegert B₁ mapping approach is combined with a stimulated echo sequence for MR imaging. The off-resonant Bloch-Siegert RF pulse is applied during the preparation period of the stimulated echo sequence, i.e. between the two (on-resonant) preparation RF pulses.

In general, a stimulated echo sequence comprises three 90° RF pulses, wherein the first two RF pulses are preparation pulses. The first preparation RF pulse excites magnetic resonance and transforms the longitudinal nuclear magnetization into transverse nuclear magnetization. The second preparation RF pulse “stores” half of the dephased transverse nuclear magnetization along the longitudinal axis. The third RF pulse is applied during the acquisition period which is temporally subsequent to the preparation period. The third RF pulse is a refocusing pulse which transforms the longitudinal nuclear magnetization into transverse nuclear magnetization again, thereby generating a so-called stimulated echo. This stimulated echo MR signal is acquired and used for imaging. MR imaging on the basis of stimulated echoes can be accelerated by replacing the 90° refocusing RF pulse by a train of low-flip angle refocusing RF pulses, wherein each refocusing RF pulse refocuses only a small portion of the longitudinal nuclear magnetization stored after the preparation period.

According to the invention, the off-resonant Bloch-Siegert RF pulse is introduced between the two preparation RF pulses in the stimulated echo sequence. In this way, the Bloch-Siegert phase shift, which is due to B₁ inhomogeneity, is stored along the longitudinal axis. A fast readout of multiple stimulated echoes is enabled by means of the refocusing RF pulses during the acquisition period. The main advantage of the approach of the invention is that the SAR level can be significantly reduced. Moreover, the stimulated echo sequence is inherently robust with respect to chemical shift and susceptibility artifacts, thus facilitating advanced acquisition schemes like EPI (echo planar imaging).

According to a preferred embodiment of the invention, the at least two preparation RF pulses each have a flip angle of essentially 90°. In this way the amplitudes of the acquired stimulated echo MR signals are maximized which is advantageous for determining the phase of the acquired stimulated echo MR signals precisely. At least one of the preparation RF pulses may be a composite pulse. For example a (β)_{0°}(2β)_{90°} composite 90° block pulse can be used for spatially non-selective excitation of magnetic resonance in order to increase the operational B₁ range. The use of such a preparation RF pulse further improves the accuracy of the method of the invention in regions of small B₁ fields, where the nominal B₁ field would not be sufficient to achieve a flip angle of 90°.

According to another preferred embodiment of the invention, a plurality of stimulated echo MR signals are generated by means of a plurality of consecutive refocusing RF pulses, each having a flip angle of less than 90°, preferably less than 45°, most preferably less than 30°. As already mentioned above, a train of refocusing RF pulses having small flip angles can be used in order to achieve a fast readout of multiple stimulated echo MR signals. The SAR burden can significantly be reduced in this way as compared to the conventional Bloch-Siegert approach. Moreover, as short as possible echo times can be used in order to minimize T₂* relaxation.

According to yet another preferred embodiment of the invention, the Bloch-Siegert RF pulse is radiated at two different frequencies during different repetitions of the imaging sequence, which frequencies are symmetrical to the on-resonance frequency. This corresponds to the conventional Bloch-Siegert technique, in which, as mentioned above, the B₁ map is derived from phase differences of two acquisitions, with the Bloch-Siegert RF pulse applied at two frequencies symmetrical around the MR resonance frequency. In this way undesired off-resonance effects due to B₀ inhomogeneity and chemical shift are eliminated.

According to a further preferred embodiment of the invention, switched magnetic field gradients are applied during the preparation period before and/or after the radiation of the Bloch-Siegert RF pulse. For example bi-polar crusher gradients can be used around the Bloch-Siegert RF pulse within the preparation period, either to spoil residual nuclear magnetization after the Bloch-Siegert RF pulse or to make the stimulated echo sequence flow-sensitive. The flow-sensitivity can be tailored to suppress a contribution from flowing blood to the acquired stimulated echo MR signals. This makes the approach of the invention applicable for cardiac applications.

Optionally at least one of the two preparation RF pulses can be applied in a frequency-selective manner, for example to selectively excite magnetic resonance in fat or water regions.

According to a further aspect of the invention, a method of MR imaging of at least a portion of a body is disclosed, wherein the method comprises the steps of:

subjecting the portion of the body to a first imaging sequence, which comprises a first composite excitation RF pulse consisting of two RF pulse components having essentially equal flip angles and being out of phase by essentially 90°;

acquiring first MR signal data;

subjecting the portion of the body to a second imaging sequence;

acquiring second MR signal data;

deriving a B₁ map indicating the spatial distribution of the RF field of the RF pulses within the portion of the body from the first and second signal data.

The proposed method is characterized by the spatial composite excitation RF pulse and can be combined with any fast imaging technique for acquisition of MR signal data. The B₁ map is derived from a voxel-wise evaluation of the phase of the acquired MR signal data. The composite excitation RF pulse αₓα_{y} generates transverse nuclear magnetization of which the phase φ₁ is directly related to the flip angle of the applied RF pulse and, hence, to the B₁ field locally effective during the RF pulse.

The phase φ₁ of the transverse nuclear magnetization generated by means of the composite excitation RF pulse according the method of the invention may depend on further parameters, like the phase of the receive system and, for example, gradient-induced eddy currents. To this end, the second imaging sequence may comprise a second composite excitation RF pulse consisting of two RF pulse components having essentially equal flip angles and being out of phase by essentially 270°. Excitation with this modified composite excitation RF pulse leads to transverse nuclear magnetization having a phase φ₂. The phase difference φ₁−φ₂ depends exclusively on the B₁ field strength, since all other disturbing effects that influence the phase will be the same for the two measurements using the first and second composite excitation RF pulse respectively. These effects are cancelled when computing the phase difference. For this purpose, a MR image is reconstructed from each of the first and second MR signal data, wherein the B₁ map is derived from the phase differences of the voxel values of the two MR images. As a result, a very accurate B₁ map is derived from a combination of the first and second MR signal data.

The above described first and second composite excitation RF pulses can be applied in a wide variety of imaging techniques for spatial encoding, the first and/or second imaging sequences may, for example, be 3D radial sequences, fast field echo (FFE) sequences, balanced fast field echo (bFFE) sequences, turbo spin echo (TSE) sequences, echo Planar Imaging (EPI) sequences, etc. Hence, the method of the invention can be combined with any fast scanning technique allowing fast and accurate B₁ mapping. The first and second imaging sequences can be designed in such a way that resonance frequency shifts in the examined portion of the body (especially water-fat shift) will not influence the phase differences used for B₁ mapping. Fast imaging sequences also enable to make the method insensitive to motion.

According to another preferred embodiment of the invention, the first and/or second composite excitation RF pulses are slice-selective, wherein the B₁ map indicates the spatial distribution of the RF field of the RF pulses within the slice selected by the first and/or second composite excitation RF pulses. For instance, the first composite excitation RF pulse is transmitted in the presence of a positive slice selection magnetic field gradient, and the second composite excitation RF pulse is transmitted during a negative slice selection magnetic field gradient. The first and second composite excitation RF pulses should be shaped in order to produce a well defined slice profile. Since in this case the B₁ field will vary over the slice profile, the resulting phases of the acquired signal data will be influenced by this distribution. In order to calculate the B₁ field, e.g. in the center of the selected slice, an appropriate set of correction factors can be determined.

In a non-slice selective version of the method of the invention the first and second excitation RF pulses will excite the entire portion of the examined body. Since the applied flip angles are typically not small (e.g. in the range of 30-150°), some delay time is required to allow T₁ relaxation. In case of slice selective excitation this delay time can be used to excite other slices and to derive the corresponding B₁ map. This multi-slice approach results in a fast B₁ mapping technique. In case a multi-transmit system is used for MR imaging, the B₁ field distributions of several different RF transmit antennae need to be determined. The afore-described multi-slice approach can be applied for exciting a set of parallel non-overlapping slices, wherein each slice is used to determine the B₁ map of one RF transmit antenna configuration (for example an individual transmit antenna or a subset from the complete array of transmit antennae). The slice orientations can be chosen such that the B₁ field is not strongly dependent on the slice position. Another application of the multi-slice approach is to increase the dynamic range of the B₁ mapping. The above described mapping technique will be particularly effective if the applied flip angle is in a specific range, e.g. between 30° and 150°. If the B₁ variations are large or an initial estimate is difficult to make, the multi-slice technique can be used to rapidly acquire signals from a series of different (parallel) slices, each acquired with a different RF power (i.e. flip angle) setting.

With increasing main magnetic field strength, also the off-resonance effects caused by B₀ inhomogeneities become more severe and effect all MR applications. Per se known B₀ shimming methods are conventionally applied to compensate for these inhomogeneities. In order to find an optimal shimming solution, an accurate and effective B₀ mapping technique is required. According to a preferred embodiment of the invention, the first imaging sequence and the second imaging sequence comprise switched magnetic field gradients for generation of gradient echo signals, wherein a B₀ map indicating the spatial distribution of the main magnetic field within the portion of the body is derived from the first and second MR signal data. This embodiment of the invention enables combined B₁ and B₀ mapping. The phase of the gradient echo signal depends on dephasing due to B₀ inhomogeneities. Hence, the voxel-wise phase shift of the gradient echo signal can be used to derive both a B₁ map and a B₀ map.

According to yet another preferred embodiment of the invention, the first and second MR signal data are acquired via two or more RF receiving antennae of the MR device, which RF receiving antennae have different spatial sensitivity profiles, wherein the first and second MR signal data are acquired without switching of magnetic field gradients for phase and/or frequency encoding. In this embodiment of the invention a multi-element RF receiving system is used, wherein a very fast and rough spatial encoding for B₁ mapping is achieved by exploiting only the spatial sensitivity profiles of the RF receiving antennae. The obtained signal phases will allow to estimate the integral of the B₁ value in the sensitivity region of the respective RF receiving antenna, weighted by the spatial sensitivity profile of this RF receiving antenna. Optionally a (small) frequency encoding magnetic field gradient may be applied for improved spatial selectivity.

The method of the invention described thus far can be carried out by means of a MR device including at least one main magnet coil for generating a uniform steady magnetic field within an examination volume, a number of gradient coils for generating switched magnetic field gradients in different spatial directions within the examination volume, at least one RF coil for generating RF pulses within the examination volume and/or for receiving MR signals from a body of a patient positioned in the examination volume, a control unit for controlling the temporal succession of RF pulses and switched magnetic field gradients, a reconstruction unit, and a visualization unit. The method of the invention is preferably implemented by a corresponding programming of the reconstruction unit, the visualization unit, and/or the control unit of the MR device.

The methods of the invention can be advantageously carried out in most MR devices in clinical use at present. To this end it is merely necessary to utilize a computer program by which the MR device is controlled such that it performs the above-explained method steps of the invention. The computer program may be present either on a data carrier or be present in a data network so as to be downloaded for installation in the control unit of the MR device.

### BRIEF DESCRIPTION OF THE DRAWINGS

The enclosed drawings disclose preferred embodiments of the present invention. It should be understood, however, that the drawings are designed for the purpose of illustration only and not as a definition of the limits of the invention. In the drawings:

FIG. 1 schematically shows a MR device for carrying out the methods of the invention;

FIG. 2 shows a diagram illustrating an imaging sequence according to a first embodiment of the invention;

FIG. 3 shows a diagram illustrating an imaging sequence according to a second embodiment of the invention;

FIG. 4 shows a diagram of the imaging sequence according to FIG. 3 with additional switched magnetic field gradients;

FIG. 5 shows a diagram illustrating the dependency of the phase differences of acquired MR signal data on the RF field.

### DETAILED DESCRIPTION OF THE EMBODIMENTS

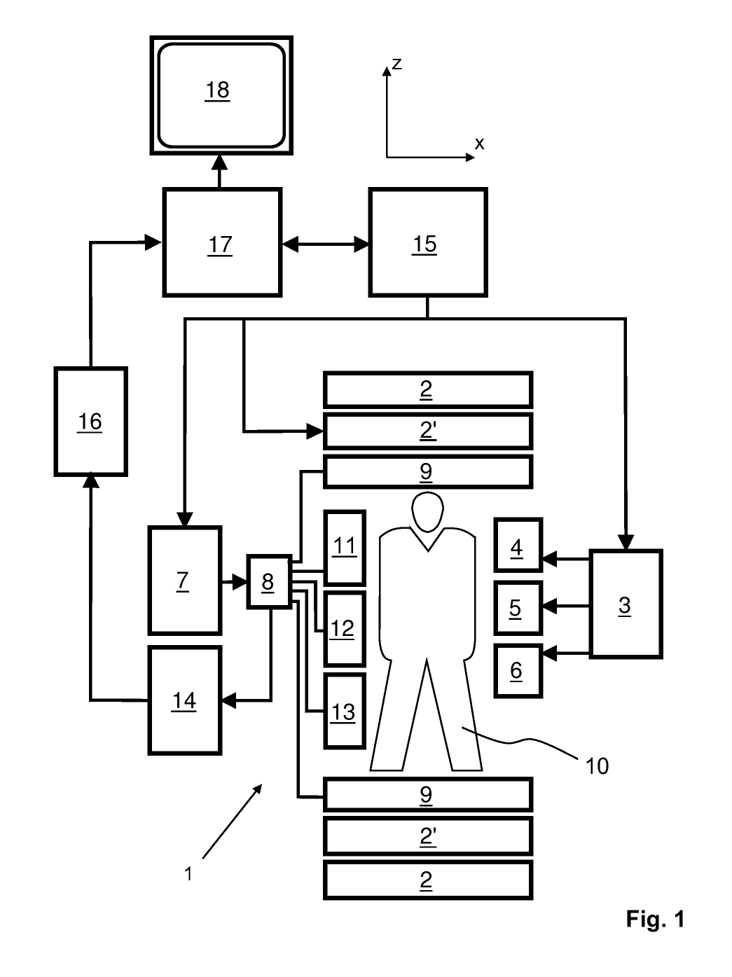

With reference to FIG. 1, a MR device 1 is shown. The device comprises superconducting or resistive main magnet coils 2 such that a substantially uniform, temporally constant main magnetic field B₀ is created along a z-axis through an examination volume. The device further comprises a set of (1^{st}, 2^{nd}, and—where applicable—3^{rd} order) shimming coils 2′, wherein the current flow through the individual shimming coils of the set 2′ is controllable for the purpose of minimizing B₀ deviations within the examination volume.

A magnetic resonance generation and manipulation system applies a series of RF pulses and switched magnetic field gradients to invert or excite nuclear magnetic spins, induce magnetic resonance, refocus magnetic resonance, manipulate magnetic resonance, spatially and otherwise encode the magnetic resonance, saturate spins, and the like to perform MR imaging.

Most specifically, a gradient pulse amplifier 3 applies current pulses to selected ones of whole-body gradient coils 4, 5 and 6 along x, y and z-axes of the examination volume. A digital RF frequency transmitter 7 transmits RF pulses or pulse packets, via a send-/receive switch 8, to a -body RF coil 9 to transmit RF pulses into the examination volume. A typical MR imaging sequence is composed of a packet of RF pulse segments of short duration which taken together with each other and any applied magnetic field gradients achieve a selected manipulation of nuclear magnetic resonance. The RF pulses are used to saturate, excite resonance, invert magnetization, refocus resonance, or manipulate resonance and select a portion of a body 10 positioned in the examination volume. The MR signals are also picked up by the body RF coil 9.

For generation of MR images of limited regions of the body 10 by means of parallel imaging, a set of local array RF coils 11, 12, 13 are placed contiguous to the region selected for imaging. The array coils 11, 12, 13 can be used to receive MR signals induced by body-coil RF transmissions.

The resultant MR signals are picked up by the body RF coil 9 and/or by the array RF coils 11, 12, 13 and demodulated by a receiver 14 preferably including a preamplifier (not shown). The receiver 14 is connected to the RF coils 9, 11, 12 and 13 via send-/receive switch 8.

A host computer 15 controls the current flow through the shimming coils 2′ as well as the gradient pulse amplifier 3 and the transmitter 7 to generate any of a plurality of MR imaging sequences, such as echo planar imaging (EPI), echo volume imaging, gradient and spin echo imaging, fast spin echo imaging, and the like. For the selected sequence, the receiver 14 receives a single or a plurality of MR data lines in rapid succession following each RF excitation pulse. A data acquisition system 16 performs analog-to-digital conversion of the received signals and converts each MR data line to a digital format suitable for further processing. In modern MR devices the data acquisition system 16 is a separate computer which is specialized in acquisition of raw image data.

Ultimately, the digital raw image data is reconstructed into an image representation by a reconstruction processor 17 which applies a Fourier transform or other appropriate reconstruction algorithms, such like SENSE or SMASH. The MR image may represent a planar slice through the patient, an array of parallel planar slices, a three-dimensional volume, or the like. The image is then stored in an image memory where it may be accessed for converting slices, projections, or other portions of the image representation into appropriate format for visualization, for example via a video monitor 18 which provides a man-readable display of the resultant MR image.

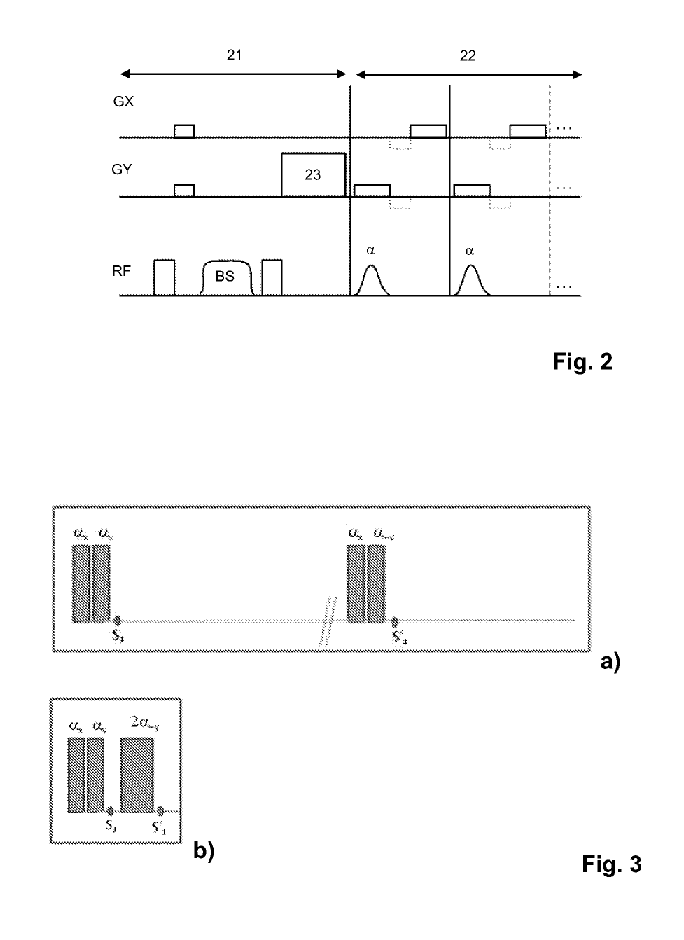

FIG. 2 shows a diagram illustrating an imaging sequence according to a first embodiment of the invention. The depicted imaging sequence is a stimulated echo sequence which is subdivided into a preparation period 21 and an acquisition period 22. Two preparation RF pulses having a flip angle of 90° are applied during the preparation period 21. An off-resonant Bloch-Siegert RF pulse BS is radiated within the time interval between the two 90° preparation RF pulses. The Bloch-Siegert RF pulse BS is a so-called Fermi-pulse having an envelope as sketched out in FIG. 2 (for more information regarding the pulse shape of the Bloch-Siegert RF pulse reference is made to the above cited article by Sacolick et al.). The RF pulses of the preparation period 21 store the B₁-inhomogeneity related Bloch-Siegert phase shift of the nuclear magnetization along the longitudinal axis. During the acquisition period 22 a plurality of refocusing RF pulses having small flip angles α are applied in order to enable a fast readout of multiple stimulated echo MR signals. A gradient echo train (for example EPI) may follow each refocusing RF pulse (the phase encoding gradients of the sequence are omitted in the diagram of FIG. 2). A gradient 23 is switched at the end of the preparation period in order to spoil residual transverse nuclear magnetization after the second preparation RF pulse. It has to be noted that the rephasing gradients of the gradient echo sequence (dashed boxes in FIG. 2) are inverted and shifted to the preparation RF pulses in order to spoil spurious MR signal contributions from longitudinal nuclear magnetization which is not prepared during the preparation period of the stimulated echo sequence.

In the embodiments depicted in FIG. 2 the preparation RF pulses are spatially non-selective. A special (β)_{0°}(2β)_{90°} composite 90° preparation RF pulse can be used for excitation during the preparation period. This increases the operational B₁ range and further improves the accuracy of B₁ mapping. Moreover, the amplitudes of the stimulated echo MR signals acquired during the acquisition period are maximized in order to enable measurement of the signal phase as precisely as possible.

In a practical embodiment of the invention, a 3D EPI sequence may be used for acquisition of stimulated echo MR signals during the acquisition period 22 (exemplary parameters: scan matrix size: 128×32×5 voxels, EPI factor 5, flip angle of the refocusing RF pulses: 15°, echo time: 6 ms, repetition time: 10 ms, duration of the Bloch-Siegert RF pulse (Fermi-pulse): 5 ms). A total scan duration of 5-10 s can be sufficient for acquiring the complete B₁ map. The B₁ map is derived from the voxel-wise phase differences of two MR images acquired in the afore described fashion with a +/−4 kHz frequency offset of the Bloch-Siegert RF pulse BS.

FIG. 3a shows a diagram illustrating an imaging sequence according to another aspect of the invention. The portion of the body 10 is subjected to a first imaging sequence comprising a first composite excitation RF pulse αₓα_{y}. This first composite excitation RF pulse generates transverse nuclear magnetization of which the phase φ₁ is directly related to the flip angle α and therefore to the B₁ field during this RF pulse. Corresponding first MR signal data S₁ are acquired after excitation by means of the first composite excitation RF pulse. The phase φ₁ is influenced by further effects, such like the phase of the receiving chain of the MR device 1 as well as by gradient eddy currents. To this end, the portion of the body 10 is subjected to a second imaging sequence comprising a second composite excitation RF pulse αₓα_{-y} generating transverse nuclear magnetization having phase φ₂. Corresponding second MR signal data S′₁ are acquired after excitation by means of the second composite excitation RF pulse. A MR image is reconstructed from each of the first and second MR signal data S₁, S′₁, wherein a B₁ map is derived from the voxel-wise phase differences of the image values of the two MR images. The phase difference φ₁−φ₂ depends exclusively on the B₁ field strength. All other undesirable effects are canceled out. The arithmetic average of the phases, ½(φ₁+φ₂), yields the phase of the B₁ field, relative to the receive chain of the used MR device.

In order to reduce scan time, a reset pulse may be applied for undoing the effect of the first composite excitation RF pulse before the application of the second composite excitation RF pulse. In the depicted case the reset pulse would be α_{-y}α₋ₓ. In combination with the second composite excitation RF pulse (αₓα_{-y}) this leads to an effective RF pulse 2α_{-y}. This case is depicted in FIG. 3b.

The dependency of the difference φ₁−φ₂ on the flip angle α is illustrated in the diagram of FIG. 5. FIG. 5 shows that the flip angle α and, hence, the B₁ field strength can directly be derived from the phase difference φ₁−φ₂.

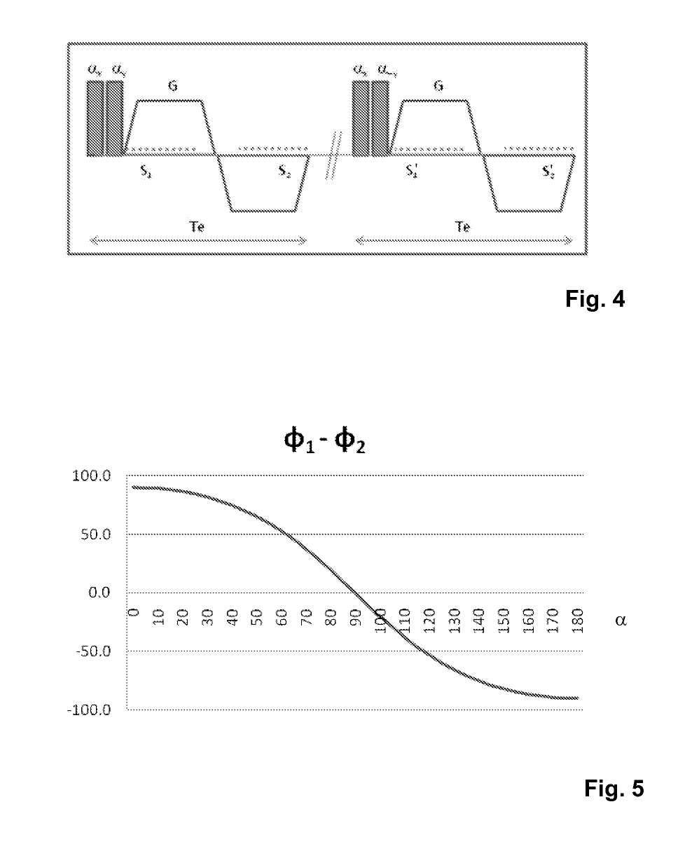

FIG. 4 illustrates the case of combined B₁ and B₀ mapping. The first and second imaging sequences comprise switched magnetic field gradients for generation of gradient echo signals. The sequence depicted in FIG. 4 can be used, for example, in a radial acquisition scheme. The phase of the signals S₁ and S′₁ can be used for B₁ mapping, as described above. The phases of the gradient echo signals S₂ and S′₂ also depend on dephasing due to B₀ inhomogeneity and chemical shift. If the echo time Tₑ is selected appropriately the influence of the water-fat shift can be canceled and the phase differences of S₂ and S′₂ can be used to derive a B₀ map. This additional information can be used to correct the B₁ calculation, since the effective flip angle α and phase of the excitation RF pulses slightly depends on the offset frequency induced by B₀ inhomogeneity.

1. Method of MR imaging of at least a portion of a body, the method comprising the steps of:
subjecting the portion of the body to an imaging sequence of RF pulses and switched magnetic field gradients, which imaging sequence is a stimulated echo sequence including:
i) at least two preparation RF pulses radiated toward the portion of the body during a preparation period,
ii) an off-resonant Bloch-Siegert RF pulse radiated toward the portion of the body during the preparation period within a time interval between the at least two preparation RF pulses, and
iii) one or more refocusing RF pulses radiated toward the portion of the body during an acquisition period temporally subsequent to the preparation period;
acquiring one or more stimulated echo MR signals during the acquisition period;
deriving a B₁ map indicating the spatial distribution of the RF field of the RF pulses within the portion of the body from the acquired stimulated echo MR signals.

2. Method of claim 1, wherein the at least two preparation RF pulses each have a flip angle of essentially 90°.

3. Method of claim 2, wherein at least one preparation RF pulse is a composite pulse.

4. Method of claim 1, wherein the at least two preparation RF pulses are spatially non-selective.

5. Method of claim 1, wherein a plurality of stimulated echo MR signals are generated by means of a corresponding plurality of consecutive refocusing RF pulses, each having a flip angle of less than 90°, preferably less than 45°, most preferably less than 30°.

6. Method of claim 5, wherein the Bloch-Siegert RF pulse is radiated at two different frequencies during different repetitions of the imaging sequence, which frequencies are symmetrical to the on-resonance frequency.

7. Method of claim 1, wherein switched magnetic field gradients are applied during the preparation period before and/or after the radiation of the Bloch-Siegert RF pulse.

8. Method of MR imaging of at least a portion of a body, the method comprising the steps of:
subjecting the portion of the body to a first imaging sequence, which comprises a first composite excitation RF pulse consisting of two RF pulse components having essentially equal flip angles and being out of phase by essentially 90°;
acquiring first MR signal data;
subjecting the portion of the body to a second imaging sequence;
acquiring second MR signal data;
deriving a B₁ map indicating the spatial distribution of the RF field of the RF pulses within the portion of the body from the first and second signal data.

9. Method of claim 8, wherein the second imaging sequence comprises a second composite excitation RF pulse consisting of two RF pulse components having identical flip angles and being out of phase by essentially 270°.

10. Method of claim 8, wherein a first MR image is reconstructed from the first MR signal data and a second MR image is reconstructed from the second MR signal data, wherein the B₁ map is derived from phase differences of the voxel values of the first and second MR images.

11. Method of claim 8, wherein the first and/or second composite excitation RF pulses are slice-selective, wherein the B₁ map indicates the spatial distribution of the RF field of the RF pulses within the slice selected by the first and/or second composite excitation RF pulses.

12. Method of claim 8, wherein the first imaging sequence and the second imaging sequence comprise switched magnetic field gradients for generation of gradient echo signals, wherein a B₀ map indicating the spatial distribution of the main magnetic field within the portion of the body is derived from the first and second MR signal data.

13. Method of claim 8, wherein the first and second MR signal data are acquired via two or more RF receiving antennae of the MR device, which RF receiving antennae have different spatial sensitivity profiles, wherein the first and second MR signal data are acquired without switching of magnetic field gradients for phase and/or frequency encoding.

14. MR device comprising at least one main magnet coil for generating a uniform, steady magnetic field within an examination volume, a number of gradient coils for generating switched magnetic field gradients in different spatial directions within the examination volume, at least one RF coil for generating RF pulses within the examination volume and/or for receiving MR signals from a body of a patient positioned in the examination volume, a control unit for controlling the temporal succession of RF pulses and switched magnetic field gradients, a reconstruction unit, and a visualization unit, wherein the MR device is arranged to perform the following steps:
subjecting the portion of the body to an imaging sequence of RF pulses and switched magnetic field gradients, which imaging sequence is a stimulated echo sequence including:
i) at least two preparation RF pulses radiated toward the portion of the body (10) during a preparation period,
ii) an off-resonant Bloch-Siegert RF pulse radiated toward the portion of the body (10) during the preparation period within a time interval between the at least two preparation RF pulses, and
iii) one or more refocusing RF pulses radiated toward the portion of the body (10) during an acquisition period temporally subsequent to the preparation period;
acquiring one or more stimulated echo MR signals during the acquisition period;
deriving a B₁ map indicating the spatial distribution of the RF field of the RF pulses within the portion of the body (10) from the acquired stimulated echo MR signals.

15. MR device comprising at least one main magnet coil for generating a uniform, steady magnetic field within an examination volume, a number of gradient coils for generating switched magnetic field gradients in different spatial directions within the examination volume, at least one RF coil for generating RF pulses within the examination volume and/or for receiving MR signals from a body of a patient positioned in the examination volume, a control unit for controlling the temporal succession of RF pulses and switched magnetic field gradients, a reconstruction unit, and a visualization unit, wherein the MR device is arranged to perform the following steps:
subjecting the portion of the body to a first imaging sequence, which comprises a first composite excitation RF pulse consisting of two RF pulse components having essentially equal flip angles and being out of phase by essentially 90°;
acquiring first MR signal data;
subjecting the portion of the body to a second imaging sequence;
acquiring second MR signal data;
deriving a B₁ map indicating the spatial distribution of the RF field of the RF pulses within the portion of the body from the first and second signal data.

16. Computer program to be run on a MR device, which computer program comprises instructions for:
generating an imaging sequence of RF pulses and switched magnetic field gradients, which imaging sequence is a stimulated echo sequence including:
i) at least two preparation RF pulses radiated toward the portion of the body (during a preparation period,
ii) an off-resonant Bloch-Siegert RF pulse radiated toward the portion of the body during the preparation period within a time interval between the at least two preparation RF pulses, and
iii) one or more refocusing RF pulses radiated toward the portion of the body during an acquisition period temporally subsequent to the preparation period;
acquiring one or more stimulated echo MR signals during the acquisition period;
deriving a B₁ map indicating the spatial distribution of the RF field of the RF pulses within the portion of the body from the acquired stimulated echo MR signals.

17. Computer program to be run on a MR device, which computer program comprises instructions for:
generating a first imaging sequence, which comprises a first composite excitation RF pulse consisting of two RF pulse components having essentially equal flip angles and being out of phase by essentially 90°;
acquiring first MR signal data;
generating a second imaging sequence;
acquiring second MR signal data;
deriving a B₁ map indicating the spatial distribution of the RF field of the RF pulses within the portion of the body from the first and second signal data.
